(19) United States
(12) Patent Application Publication
(10) Pub. No.: US 2016/0044839 A1
(43) Pub. Date: Feb. 11, 2016

(54) ELECTROMAGNETIC WAVE SHIELDING SHEET AND SEMICONDUCTOR APPARATUS

(71) Applicant: SHIN-ETSU CHEMICAL CO., LTD., Tokyo (JP)

(72) Inventors: Saiko AKAHANE, Annaka (JP); Hideki AKIBA, Annaka (JP); Toshio SHIOBARA, Annaka (JP)

(21) Appl. No.: 14/755,767

(22) Filed: Jun. 30, 2015

(30) Foreign Application Priority Data
Aug. 5, 2014 (JP) 2014-159278

(51) Int. Cl. H05K 9/00

(52) U.S. Cl. CPC H05K 9/0084

(57) ABSTRACT

The present invention provides an electromagnetic wave shielding sheet including a surface-treated fibrous film and a conductive layer, the surface-treated fibrous film having a conventional bending rigidity 3 to 100 times larger than a conventional bending rigidity of a untreated fibrous film as measured according to a procedure described in Japanese Industrial Standards R 3420, the conductive layer being composed of a metallic mesh. The electromagnetic wave shielding sheet has sufficient electromagnetic wave shielding property, high strength, flexibility, excellent dimensional stability, and high heat resistance and configured to inhibit warp and swell during high temperature heating.

### BACKGROUND OF THE INVENTION

1. Field of the Invention

The present invention relates to an electromagnetic wave shielding sheet including a surface-treated fibrous film and a conductive layer, and further relates to a semiconductor apparatus using the same.

2. Description of the Related Art

In electronic/electric devices, electromagnetic wave noises are generated from electronic parts such as a semiconductor device or a power supply built therein. The generated electromagnetic wave noises threaten to interfere with other built-in electronic parts such as a radio system or to leak outside thereby adversely affecting other electronic parts (e.g., remote control equipment, information processing equipment, etc.). In recent years, as electronic/electric devices advance toward high functionality and high-speed processing, the electromagnetic wave noises generated from the electronic parts or the power supply are increasing, which results in failures or a malfunction in the electronic/electric devices. Therefore, measures against the electromagnetic wave noises are becoming very important.

One of parts used in the measures is an electromagnetic wave shielding sheet. The electromagnetic wave shielding sheet can attenuate the electromagnetic wave noises emitted outside and the electromagnetic wave noises from an outside, and prevent a malfunction in the electronic device, for example, by covering the semiconductor device.

A metal plate made of copper, aluminum, or others is most effective as the electromagnetic wave shielding sheet. However, there is a disadvantage that the metal plate cannot exhibit flexibility when a substrate having semiconductor devices mounted thereon or a cable is covered with it since the metal plate is heavy and has high rigidity.

Therefore, a metal foil or mesh made of copper, aluminum, or others has been used as the electromagnetic wave shielding sheet. Unfortunately, since the density of these materials is still high, the problem of increase in weight remains to be solved, and flexibility of the electromagnetic wave shielding sheet is unsatisfied. On the other hand, there is another disadvantage that as the metal foil or mesh makes thin in view of weight and flexibility, the self-standing property itself is impaired and the workability becomes too low to handle it alone, and therefore it is not suitable for mass-production.

In recent years, for improving workability of the metal foil or mesh, an electromagnetic wave shielding sheet in which a metal foil or mesh is combined with a support for supporting it is being developed actively. As the support, glass, a resin plate, or a resin film is mainly used. The resin film is useful in view of flexibility, but polyethylene terephthalate resin or a polyurethane resin is mainly used (Patent Documents 1 and 2) and examination of the resins is not enough. Although a thin resin film has flexibility, its strength is weak and the problems of heat resistance and workability still remain.

### PRIOR ART REFERENCES

### Patent Documents

[Patent Document 1] Japanese Patent No. 4887442

[Patent Document 2] Japanese Patent Application Publication No. H10-163675

### SUMMARY OF THE INVENTION

The present invention has been accomplished in view of the above-mentioned circumstances, and an object thereof is to provide an electromagnetic wave shielding sheet having sufficient electromagnetic wave shielding property, high strength, flexibility, excellent dimensional stability, and high heat resistance and configured to inhibit swell and warp during high temperature heating.

To achieve this object, the present invention provides an electromagnetic wave shielding sheet comprising a surface-treated fibrous film and a conductive layer,

the surface-treated fibrous film having a conventional bending rigidity 3 to 100 times larger than a conventional bending rigidity of a untreated fibrous film as measured according to a procedure described in Japanese Industrial Standards R 3420, the conductive layer being composed of a metallic mesh.

Such an electromagnetic wave shielding sheet has sufficient electromagnetic wave shielding property, and since both properties of high strength and flexibility are maintained by the surface-treated fibrous film, excellent dimensional stability is provided. Further, since the metal constituting the conductive layer is mesh, a high-reliability electromagnetic wave shielding sheet having high heat resistance and configured to inhibit swell and warp during high temperature heating can be obtained.

In particular, an open area ratio of the metallic mesh is preferably 10% or more and 90% or less.

When such a conductive layer is employed, the surface-treated fibrous film, which serves as a support, is not fully covered. Therefore, even if gas is generated from the support during high temperature heating, the gas is escaped through the mesh, whereby an electromagnetic wave shielding sheet configured to inhibit swell and having sufficient electromagnetic wave shielding property can be obtained.

Also, a thickness of the metallic mesh is preferably 0.05 μm or more and 200 μm or less.

When such a conductive layer is employed, an electromagnetic wave shielding sheet having good processability and flexibility can be obtained.

Also, the electromagnetic wave shielding sheet is preferably bendable at 90° or more.

Such an electromagnetic wave shielding sheet can be suitably used as a flexible electromagnetic wave shielding sheet.

Also, it is preferred that the surface-treated fibrous film include glass fibers, and a part or all of the glass fibers be surface-treated and bundled by a cured product of an organosilicon compound.

When such a surface-treated fibrous film is employed, an electromagnetic wave shielding sheet in which the fibers are fixed and which has higher strength and flexibility can be obtained.

In addition, the organosilicon compound is preferably one or more compounds selected from the group consisting of alkoxysilane, polysilazane, partial hydrolysis condensates thereof, a silicone-modified varnish, and an addition curing type silicone resin.

Further, the surface-treated fibrous film preferably contains a filler.

When such a surface-treated fibrous film is employed, an electromagnetic wave shielding sheet having more excellent dimensional stability and mechanical strength can be obtained.

Also, the electromagnetic wave shielding sheet preferably has the configuration that the conductive layer and a layer having a sheet of the surface-treated fibrous film or two or more sheets of the surface-treated fibrous film being laminated are laminated alternately and repeatedly one or more times.

Such an electromagnetic wave shielding sheet has both flexibility and electromagnetic wave shielding property.

Also, the metallic mesh is preferably divided into two or more regions.

Dividing the metallic mesh into two or more regions enables the electromagnetic wave shielding sheet to be further inhibited from warping.

Furthermore, the present invention provides a semiconductor apparatus prepared by using the above-described electromagnetic wave shielding sheet.

Thus, since the electromagnetic wave shielding sheet of the present invention has flexibility and high strength, it is applicable to a semiconductor apparatus that requires flexibility and high heat resistance or a high-performance semiconductor apparatus that requires sufficient electromagnetic wave shielding property.

When the electromagnetic wave shielding sheet according to the present invention is employed, a high-reliability electromagnetic wave shielding sheet having sufficient electromagnetic wave shielding property, flexibility, excellent dimensional stability, and high heat resistance and configured to inhibit swell and warp during high temperature heating can be obtained. Also, in the present invention, both flexibility and mechanical strength can be provided by using the surface-treated fibrous film as the support. Further, using the surface-treated fibrous film in which the organosilicon compound is used for the surface treatment enables an electromagnetic wave shielding sheet excellent in heat resistance to be obtained. Thus, the electromagnetic wave shielding sheet of the present invention can be suitably used in the field requiring flexibility, workability, and reliability.

Moreover, since the electromagnetic wave shielding sheet of the present invention has flexibility and high strength, it is applicable to a semiconductor apparatus that requires flexibility and high heat resistance or a high-performance semiconductor apparatus that requires sufficient electromagnetic wave shielding property.

### BRIEF DESCRIPTION OF THE DRAWINGS

FIG. 1 shows a perspective view of an exemplary electromagnetic wave shielding sheet of the present invention;

FIG. 2 shows a plane schematic view of the conductive layer of the electromagnetic wave shielding sheet prepared in Examples 1 and 2 and Comparative Example 4;

FIG. 3 shows a plane schematic view of the conductive layer of the electromagnetic wave shielding sheet prepared in Example 3;

FIG. 4 shows a magnified plane schematic view of the conductive layer of the electromagnetic wave shielding sheet prepared in Examples;

FIG. 5 shows a sectional view of the electromagnetic wave shielding sheet and the semi-cylindrical shaped housing used for the flexibility test in Examples; and

FIG. 6 shows a sectional view of the surface-treated fibrous film and the semi-cylindrical shaped housing used for the flexibility test in Production Examples.

### DETAILED DESCRIPTION OF THE PREFERRED EMBODIMENTS

As described above, the electromagnetic wave shielding sheet having sufficient electromagnetic wave shielding property, high strength, flexibility, excellent dimensional stability, and high heat resistance and configured to inhibit swell and warp during high temperature heating has been demanded.

The present inventor has diligently studied to accomplish the objects and consequently found that the objects can be accomplished by providing an electromagnetic wave shielding sheet using a surface-treated fibrous film having high strength and excellent flexibility and a conductive layer composed of a metallic mesh, thereby bringing the invention to completion.

In the following, the present invention is described in detail, but the present invention is not limited thereto.

The present invention is directed to an electromagnetic wave shielding sheet comprising a surface-treated fibrous film and a conductive layer,

the surface-treated fibrous film having a conventional bending rigidity 3 to 100 times larger than a conventional bending rigidity of a untreated fibrous film as measured according to a procedure described in Japanese Industrial Standards R 3420, the conductive layer being composed of a metallic mesh.

### <Electromagnetic Wave Shielding Sheet>

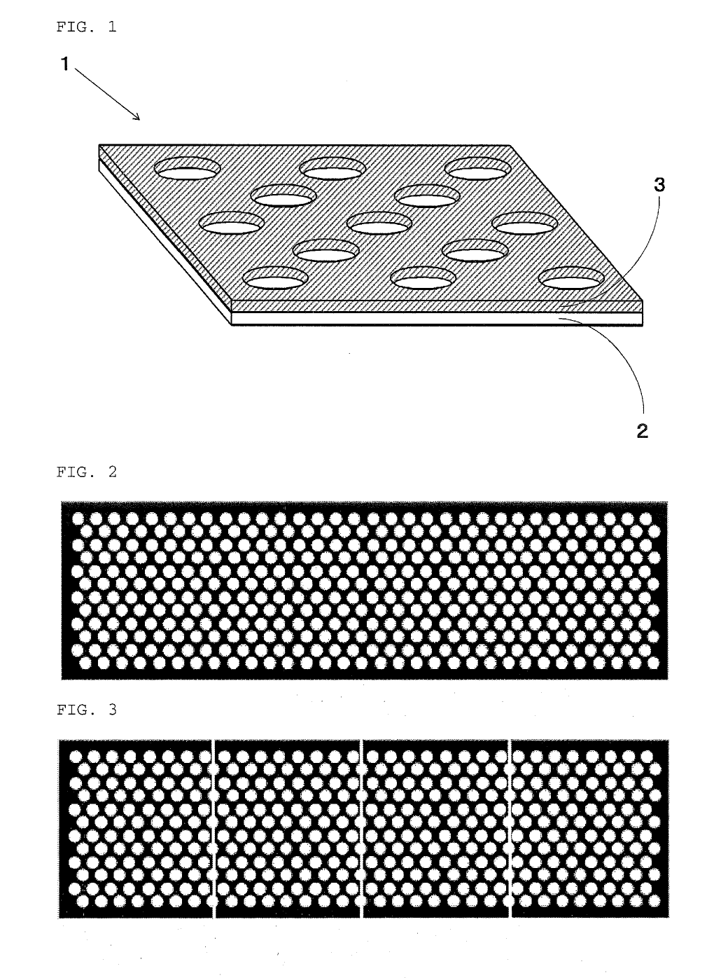

FIG. 1 shows an exemplary electromagnetic wave shielding sheet of the present invention.

The electromagnetic wave shielding sheet 1 of the present invention includes a surface-treated fibrous film 2 and a conductive layer 3 composed of a metallic mesh formed on the surface-treated fibrous film 2.

In the following, the electromagnetic wave shielding sheet of the present invention is described in more detail.

### <Conductive Layer>

In the present invention, as a material constituting the conductive layer composed of the metallic mesh, various metals can be generally used. Further, metals, metal oxides, and other compound materials can also be used as long as the requirements for the electromagnetic wave shielding property are met. In particular, metals are preferable materials since they are inexpensive and easy to be processed. Illustrative examples of the metal species to be used include Au, Ag, Cu, Ni, Cr, Fe, Al, Zn, Ti, Ta, Mo, Co, various other simple metals, and various alloys.

The metallic mesh used in the present invention is made of a material having good electrically conductivity as mentioned above and formed of, for example, finely line, circle, or polygon; and any pattern is usable as long as it has openings on its surface. The shape of the whole conductive layer is not particularly limited, and may be designed so as to have any shape such as square, rectangular, or random strip shape.

In the present invention, the open area ratio of the metallic mesh is preferably 10% or more and 90% or less, more preferably 20% or more and 80% or less, much more preferably 30% or more and 75% or less. Here, the “open area ratio” denotes the ratio of the total area of the openings to the total area of the conductive layer.

If the open area ratio is 10% or more, swell can be inhibited even if gas is generated from the support during high temperature heating since the gas is escaped through the openings, therefore heat resistance becomes excellent so that it is preferred. If the open area ratio is 90% or less, the electromagnetic wave shielding property is fully exhibited.

In the present invention, the thickness of the metallic mesh is preferably 0.05 μm or more and 200 μm or less, more preferably 0.1 μm or more and 150 μm or less, much more preferably 0.3 μm or more and 100 μm or less.

The reason why these thicknesses are preferable is that if the thickness is 0.05 μm or more, the processability is excellent, and if the thickness is 200 μm or less, the electromagnetic wave shielding sheet has flexibility.

The metallic mesh constituting the conductive layer is preferably divided into two or more regions.

Dividing the metallic mesh into two or more regions enables the electromagnetic wave shielding sheet to be further inhibited from warping. Generally, the combination of two materials different in linear expansion coefficient and elasticity tends to cause warping. However, if the metallic mesh is divided into two or more regions, the warping can be inhibited even when it is laminated together with the surface-treated fibrous film which serves as a support and has different linear expansion coefficient and elasticity.

### [Surface-Treated Fibrous Film]

In the electromagnetic wave shielding sheet of the present invention, the fibrous film a surface of which has been treated (hereinafter referred to as “surface-treated fibrous film”) mainly serves as a support. In addition, the surface-treated fibrous film used in the present invention is preferably a film obtained by subjecting a glass cloth made of glass fibers to surface treatment. More specifically, a film in which a part or all of the glass fibers in the glass cloth are surface-treated and bundled by a cured product of an organic compound containing a silicon atom (hereinafter referred to as “organosilicon compound”) is preferred.

The surface-treated fibrous film used in the present invention has a conventional bending rigidity of a cloth measured according to a procedure described in Japanese Industrial Standards (JIS) R 3420 of 3 to 100 times larger than a conventional bending rigidity of an untreated fiber film. This multiple is used as an index showing degree of change from so-called “woven fabric” form to “film” form by subjecting a sheet of the fibrous film to surface treatment, and it is preferably 5 to 60 times, more preferably 10 to 40 times.

If the conventional bending rigidity is less than 3 times, the objective dimensional stability and fiber fixation are insufficient, and the electromagnetic wave shielding sheet with high strength cannot be obtained. If it exceeds 100 times, the surface-treated fibrous film becomes too hard, and flexibility of the electromagnetic wave shielding sheet is impaired to generate cracks, etc.

In the case that a material containing glass fibers is used as the surface-treated fibrous film and an organosilicon compound is used for the surface treatment, to satisfy the above-mentioned characteristics, the amount of the organosilicon compound to be adhered onto the fibrous film is preferably 2 to 90% by mass, more preferably 5 to 70% by mass, much more preferably 10 to 60% by mass based on 100% by mass of the fibrous film after surface treatment.

If the adhesion amount is 2% by mass or more, the above-mentioned characteristics can be satisfied, and as a result, characteristics such as heat resistance, dimensional stability, and self-standing property are good so that it is preferred. If the adhesion amount is 90% by mass or less, it is possible to prevent lowering of heat resistance and reducing of flexibility.

When a glass fiber film is used in the present invention, it may be subjected to fiber-opening processing with column-like flow or water flow caused by a high-frequency vibration method. Further, as the glass fiber adapted to the present invention, any glass fiber made of E-glass, A-glass, D-glass, S-glass, or so on can be used. The E-glass is preferred in view of cost and availability. If higher properties (such as high heat resistance and low impurity) are required, quartz glass is preferred.

Such a glass cloth preferably has a weaving density of the fiber of 10 to 200 yarns/25 mm, more preferably 15 to 100 yarns/25 mm, and preferably has a mass of 5 to 400 g/m², more preferably 10 to 300 g/m². If these values are within the above ranges, bundling by the surface treatment can be effectively done, and properties such as heat resistance, dimensional stability, self-standing property, etc., can be easily obtained.

As the method of weaving such a glass cloth, plain weave, satin weave, basket weave, etc., may be used. Also, the glass fiber may be prepared by weaving two glass fibers both or one of which is textured. Further, a 3-spindle braided glass fiber becomes a surface-treated fibrous film having higher strength and reliability. Moreover, a non-woven fabric or fabrics in which long fibers are arrayed along a certain direction can also be used.

When a bundling agent is applied to the glass cloth, it is desired that the agent is previously removed since it occasionally disturbs the treatment with an organosilicon compound.

The organosilicon compound to be used for the surface treatment of the above-mentioned glass cloth may be one or more compounds selected from the group consisting of alkoxysilane, polysilazane, partial hydrolysis condensates thereof, a silicone-modified varnish, and an addition curing type silicone resin.

Examples of the alkoxysilane include tetraalkoxysilanes such as tetramethoxysilane and tetraethoxysilane; alkylalkoxysilanes such as trimethylmethoxysilane, trimethylethoxysilane, dimethyldimethoxysilane, dimethyldiethoxysilane, methyltrimethoxysilane, methyltriethoxysilane, n-propyltriethoxysilane, hexyltrimethoxysilane, octyltriethoxysilane, decyltrimethoxysilane, and 1,6-bis(trimethoxysilyl)hexane; arylalkoxysilanes such as methylphenyldimethoxysilane, methylphenyldiethoxysilane, diphenyldimethoxysilane, diphenyldiethoxysilane, phenyltrimethoxysilane, phenyltriethoxysilane, p-styryltrimethoxysilane; hydroxyalkoxysilanes such as hydroxytrimethoxysilane and hydroxytriethoxysilane; alkenylalkoxysilanes such as vinyltrimethoxysilane and vinyltriethoxysilane; epoxy group-containing alkoxysilanes, such as 3-glycidoxypropyltrimethoxysilane, 3-glycidoxypropylmethyldimethoxysilane, 3-glycidoxypropyl-triethoxysilane, 3-glycidoxypropylmethyldiethoxysilane, and 2-(3,4-epoxycyclohexyl)ethyltrimethoxysilane; (meth)acrylic group-containing alkoxysilanes such as 3-methacryloxypropyltrimethoxysilane, 3-methacryloxypropylmethyldimethoxysilane, 3-methacryloxypropyltriethoxysilane, 3-methacryloxypropyl-methyldiethoxysilane, and 3-acryloxypropyltrimethoxy-silane; amino group-containing alkoxysilanes such as N-2-(aminoethyl)3-aminopropyltrimethoxysilane, N-2-(aminoethyl)3-aminopropylmethyldimethoxysilane, 3-aminopropyltrimethoxysilane, 3-aminopropyltriethoxysilane, N-phenyl-3-aminopropyltrimethoxysilane, 3-allylaminopropyltrimethoxysilane, N-(N-vinylbenzyl)-2-aminoethyl-3-aminopropyltrimethoxysilane and hydrochloride thereof, N-(N-vinylbenzyl)-2-aminoethyl-3-aminopropylmethyldimethoxysilane and hydrochloride thereof; isocyanate alkoxysilanes such as 3-isocyanate propyltriethoxysilane and tris-(trimethoxysilylpropyl) isocyanurate; and alkoxysilane compounds such as 3-ureidopropyltriethoxysilane, 3-chloropropyltrimethoxy-silane, 3-mercaptopropyltrimethoxysilane, 3-mercaptopropylmethyldimethoxysilane, and bis(trisethoxysilylpropyl)tetrasulfide. These alkoxysilanes may be used alone or in combination of two or more kinds. Preferable examples include methyltrimethoxysilane, vinyltrimethoxysilane, 3-glycidoxypropyltrimethoxysilane, and 3-aminopropyltrimethoxysilane, but it is not limited thereto.

Also, partial hydrolysis condensates of one kind or two or more kinds of the above-mentioned alkoxysilanes may be used. The partial hydrolysis condensates may be optionally prepared by adding a known condensation catalyst, or a commercially available product may be used. Examples of the commercially available product include an epoxy group-containing alkoxysilane oligomer X-41-1059A (available from Shin-Etsu Chemical Co., Ltd.) and an amino group-containing alkoxysilane oligomer X-40-2651 (available from Shin-Etsu Chemical Co., Ltd.).

Examples of the polysilazane include compounds such as 1,1,3,3-tetramethyldisilazane, hexamethyldisilazane, 1,3-divinyl-1,1,3,3-tetramethyldisilazane, and 1,1,3,3,5,5-hexamethylcyclotrisilazane, but it is not limited thereto.

As the silicone-modified varnish, various silicone-modified varnishes such as an alkyd-modified varnish, a polyester-modified varnish, an epoxy-modified varnish, and an acryl-modified varnish may be used, and it may be appropriately selected depending on the final use and the purpose.

As the addition curing type silicone resin, a composition comprising an unsaturated group-containing organopolysiloxane which are composed of SiO_{4/2} units, R¹SiO_{3/2} units, R¹₍₂₋ₙ₎R²ₙSiO_{2/2} units (here, 0≦n≦2), and R¹₍₃₋ₘ₎R²ₘSiO_{1/2} units (here, 0≦m≦3), an organopolysiloxane containing at least one hydrosilyl group, and a platinum catalyst with an effective amount for curing is used, and may be appropriately selected depending on the final use and the purpose.

Here, the above-mentioned R¹ is a monovalent saturated hydrocarbon group having 1 to 10 carbon atoms or a monovalent aromatic hydrocarbon group, R² is a monovalent unsaturated hydrocarbon group having 2 to 8 carbon atoms, and at least one R² is contained, and in a saturated group-containing organopolysiloxane, SiO_{4/2} units or R¹SiO_{3/2} units are contained. It is particularly preferable that R¹ be a methyl group, an ethyl group, a propyl group, a cyclohexyl group, or a phenyl group, and R² be a vinyl group or an allyl group. By containing the SiO_{4/2} units or the R¹SiO_{3/2} units, it is possible to firmly fix the fiber while suppressing brittleness.

In the present invention, fibers such as inorganic fibers e.g. carbon fiber and ceramic fiber; novel heat-resistant fibers e.g. aramid-based fiber and phenolic-based fiber; etc., are also applicable in place of the glass fiber.

The surface-treated fibrous film may contain a filler, if necessary. The filler may be used alone or in combination of two or more kinds. The filler may be added for the purpose of lowering the linear expansion coefficient, and improving the thermal conductivity or strength. The filler may be any conventionally known filler, and examples thereof include silica such as precipitated silica, fumed silica, fused silica, fused spherical silica, and crystalline silica, fumed titanium dioxide, zinc oxide, silicon nitride, aluminum nitride, boron nitride, antimony trioxide, alumina, zirconium oxide, zinc sulfide, magnesium oxide, and barium sulfate. In particular, fused silica, fused spherical silica, titanium oxide, and alumina are preferred.

The adding amount of the filler when an organosilicon compound is used for the surface treatment is preferably in the range of 900 parts by mass or less (0 to 900 parts by mass) per 100 parts by mass of the organosilicon compound in view of the linear expansion coefficient and strength of the resulting surface-treated fibrous film, and more preferably 600 parts by mass or less (0 to 600 parts by mass), much more preferably 10 to 600 parts by mass, particularly preferably 50 to 500 parts by mass.

The average particle diameter and the shape of the component of the filler are not particularly limited. The average particle diameter of the component of the filler is generally 0.5 to 50 μm, and in view of moldability and flowability of the organosilicon compound to be used for the surface treatment, it is preferably 1 to 10 μm, more preferably 1 to 5 μm. Incidentally, the average particle diameter can be obtained as a mass average value D₅₀ (or a median diameter) in the particle diameter distribution measurement by a laser beam diffraction method.

A method of producing the surface-treated fibrous film is not particularly limited, and common methods of processing a glass fiber can be applied. For example, in the case of a glass fiber to which a bundling agent has been attached, it is used after removing the agent by a known manner. Alternatively, a glass fiber in which a bundling agent has previously been removed may be used.

Suitable examples of the coating solution to be used for the surface treatment include, in general, a solution in which water or an organic solvent such as alcohols, ketones, glycol ethers, hydrocarbon non-polar solvents e.g. toluene, xylene, hexane, and heptane, ethers, etc., is added to an alkoxysilane. Further, a pH adjusting agent such as formic acid, acetic acid, propionic acid, oxalic acid, and aqueous ammonia; a pigment, a dye, a filler, a surfactant, a thickener, etc., may also be added. Moreover, a condensation catalyst of an alkoxy group, for example, various kinds of organometallic compounds or amine compounds, etc., may be added to promote the curing. Further, a solution to which the above-mentioned filler has been added may be prepared as a solution or a dispersion, if necessary.

In this case, an aqueous type coating solution is preferred considering the coating environment. A silane coupling agent, KBM-903 (available from Shin-Etsu Chemical Co., Ltd.) has excellent stability in an aqueous system and good solubility so that it is preferable as the organosilicon compound.

As a method of applying the coating solution to the fibrous film in the present invention, common coating methods to a glass fiber can be used. Typical examples of the coating method include a direct gravure coater, a chamber doctor coater, an offset gravure coater, a roll-kiss coater, a reverse kiss coater, a bar coater, a reverse roll coater, a slot die, an air doctor coater, a normal rotation roll coater, a blade coater, a knife coater, a dip coater, an MB coater, and an MB reverse coater. Among these, a direct gravure coater, offset coater, and a dip coater coating system are preferred for manufacturing the surface-treated fibrous film.

Although the conditions are depending on the organosilicon compound to be used, examples of the steps are, drying after applying, heating for curing while raising the temperature from room temperature to 300° C. for 1 minute to 24 hours. In view of productivity, cost, and workability, the surface-treated fibrous film is preferably manufactured by heat treatment from room temperature to 250° C. for 3 minutes to 4 hours, more preferably from room temperature to 230° C. for 5 minutes to 1 hour.

The coating solution is, for example, a solution in which the above-mentioned organosilicon compound is diluted with a solvent. Examples of the solvent include water and an organic solvent, and these may be used alone or in combination of two or more kinds. Examples of the organic solvent include alcohols such as methanol, ethanol, isopropanol, and n-butanol; ketones such as acetone, methyl ethyl ketone, and methyl isobutyl ketone; glycol ethers such as ethylene glycol and propylene glycol; aliphatic hydrocarbons such as hexane and heptane; aromatic hydrocarbons such as toluene and xylene; and ethers such as diethyl ether, diisopropyl ether, and di-n-butyl ether. It is also possible to further add an organic acid such as formic acid, acetic acid, propionic acid, and oxalic acid; a pH adjusting agent such as aqueous ammonia; a pigment, a filler, a surfactant, a thickener, etc., to the diluted solution.

In addition, an alkoxy group condensation catalyst may also be added, and examples thereof include an organometallic compound catalyst such as an organotin compound, an organotitanium compound, and an organobismuth compound; and an amine compound.

The organometallic compound condensation catalyst may be exemplified by metallic Lewis acids. Illustrative examples thereof include organotin compounds such as dibutyltin dimethoxide, dibutyltin diacetate, dibutyltin dioctoate, dibutyltin dilaurate, dibutyltin bis(acetyl-acetonato), dibutyltin bis(benzylmaleate), dimethyltin dimethoxide, dimethyltin diacetate, dioctyltin dioctoate, dioctyltin dilaurate, tin dioctoate, and tin dilaurate; organotitanium compounds such as tetraisopropyl titanate, tetra-normal-butyl titanate, tetra-tertiary-butyl titanate, tetra-normal-propyl titanate, tetra-2-ethylhexyl titanate, diisopropyl-di-tertiary-butyl titanate, dimethoxytitanium bisacetylacetonato, diisopropoxytitanium bisethylacetoacetate, di-tertiary-butoxytitanium bisethylacetoacetate, and di-tertiary-butoxytitanium bismethylacetoacetate; and organobismuth compounds such as bismuth tris(2-ethylhexanoate) and bismuth tris(neodecanoate). These may be used alone or in combination of two or more kinds.

Examples of the amine compound include hexylamine, di-2-ethylhexylamine, N,N-dimethyldodecylamine, di-n-hexylamine, dicyclohexylamine, di-n-octylamine, and hexamethoxymethylmelamine.

Among these condensation catalysts, organotitanium compounds are particularly preferable.

### [Layer Composed of Other Component]

The electromagnetic wave shielding sheet of the present invention may contain a layer composed of the other component, if necessary.

Particularly, in the present invention, an adhesive layer composed of an adhesive resin composition may be placed between the surface-treated fibrous film and the conductive layer, between two surface-treated fibrous films, or both of these. As the adhesive resin composition, a thermosetting resin is preferably used. Such an electromagnetic wave shielding sheet is excellent in heat resistance and discoloration resistance and has high mechanical strength since a thermosetting resin is used as the adhesive layer.

The thermosetting resin used as the adhesive layer may be any known thermosetting resin so long as it has adhesiveness. Examples thereof include a silicone resin, an epoxy resin, and a phenol resin, and a silicone resin and an epoxy resin are particularly preferred.

The adhesive resin composition may contain a filler, if necessary. The filler may be used alone or in combination of two or more kinds. The filler may be added for the purpose of lowering the linear expansion coefficient and improving the thermal conductivity or strength of the electromagnetic wave shielding sheet. The filler may be any known filler, and the filler described in the surface-treated fibrous film mentioned above is preferably used.

Also, in the present invention, an adhesion-improving treatment is preferably applied to either or both of the surface-treated fibrous film and the adhesive layer to improve adhesion between the surface-treated fibrous film and the adhesive layer. The adhesion-improving treatment may be exemplified by a discharge treatment such as normal pressure plasma treatment, corona discharge treatment, and low temperature plasma treatment; a surface swelling treatment by an alkali, a desmear treatment by permanganic acid, a primer treatment by a silane coupling agent, etc.

### [Method of Producing Electromagnetic Wave Shielding Sheet]

In the electromagnetic wave shielding sheet 1 of the present invention, as a method of forming the conductive layer 3 on the surface-treated fibrous film 2, there may be mentioned a subtractive process, electroless plating, electroplating, physical vapor deposition such as vacuum deposition and sputtering, a method of coating or dipping with a coating composition containing a metal filler, or a method of bonding a mesh made of a conductive fiber base, but the method is not limited thereto.

When these method are employed, the conductive layer 3 composed of a metallic mesh can be readily formed.

The surface-treated fibrous film used in the electromagnetic wave shielding sheet of the present invention may be a sheet of the surface-treated fibrous film which has been subjected to the heat treatment by the method mentioned above, or two or more sheets of the surface-treated fibrous film may be stacked and bonded each other to form a surface-treated fibrous film layer, if necessary. As a method of bonding the surface-treated fibrous films, there may be mentioned a pressing method, a laminating method, etc. Conditions of the pressing method and the laminating method may be appropriately determined depending on characteristics of the surface-treated fibrous film. Also, the surface-treated fibrous films may be bonded together with the conductive layer at one time.

In the present invention, as the method of forming the adhesive layer on the surface-treated fibrous film, for example, at least one of a laminating method, a dipping method, a spray-coating method, and a bar-coating method can be used. In particular, the laminating method and the dipping method are preferable.

In the present invention, the conductive layer and the layer having a sheet of the surface-treated fibrous film or two or more sheets of the surface-treated fibrous film being laminated may be laminated alternately and repeatedly one or more times to provide the electromagnetic wave shielding sheet. Examples of the method of alternately and repeatedly laminating the layers include, as for the surface-treated fibrous film, a pressing method and a laminating method, as for the conductive layer, a subtractive process, electroless plating, electroplating, physical vapor deposition such as vacuum deposition and sputtering, and a method of coating or dipping with a coating composition containing a metal filler; but the method is not limited thereto. In view of flexibility, the number of laminating is preferably reduced.

If necessary, the outermost layer of the electromagnetic wave shielding sheet may be plated with metal. When metal plating is performed, it can be done according to the conventional manner and is not particularly limited. There may be mentioned, for example, a method in which a metal coating layer is formed on the surface-treated fibrous film by electroless plating. The metal film layer to be formed is preferably selected from Ni, Pd, Au, Ag, Sn, or an alloy made of two or more these metals, for example, a Ni—Au alloy, a Ni—Ag alloy, a Ni—Pd—Au alloy, etc. Also, after the electroless plating, the film may be thickened by electroplating.

The electromagnetic wave shielding sheet manufactured by the above-described method can exhibit an excellent flexibility. More specifically, when the electromagnetic wave shielding sheet 1 is bent along with the housing 4 having a radius of 75 mm as shown in FIG. 5, it is desired that it can be bent preferably 90° or more, more preferably 120° or more and 180° or lower, much more preferably 150° or more and 180° or lower.

Also, the electromagnetic wave shielding sheet of the present invention preferably has an electromagnetic wave shielding property of 30 dB or more in the range of 100 MHz to 1000 MHz when the test is conducted by the following measuring method, for example.

Measuring method: KEC method (KEC: Kansai Electronic Industry Development Center)

### Measuring Conditions:

Measuring frequency; 100 MHz to 1000 MHz

Distance between transmitting part and receiving part; 10 mm

Temperature and humidity in test room; 20° C./65% RH

When the electromagnetic wave shielding property in the electromagnetic wave shielding sheet of the present invention is 30 dB or more, the electromagnetic wave shielding sheet having sufficient electromagnetic wave shielding property can be obtained.

When the electromagnetic wave shielding sheet according to the present invention is employed, a high-reliability electromagnetic wave shielding sheet having sufficient electromagnetic wave shielding property, flexibility, excellent dimensional stability, and high heat resistance and configured to inhibit swell and warp during high temperature heating can be obtained. Also, in the present invention, both flexibility and mechanical strength can be provided by using the surface-treated fibrous film as the support. Further, using the surface-treated fibrous film in which the organosilicon compound is used for the surface treatment enables an electromagnetic wave shielding sheet excellent in heat resistance to be obtained. Thus, the electromagnetic wave shielding sheet of the present invention can be suitably used in the field requiring flexibility, workability, and reliability.

### <Semiconductor Apparatus>

The above-described electromagnetic wave shielding sheet can be combined with an electrical part having semiconductor devices mounted thereon to provide a semiconductor apparatus. As mentioned above, since the electromagnetic wave shielding sheet of the present invention has characteristics of being flexible and having high strength, it is applicable to a semiconductor apparatus that requires flexibility and high heat resistance or a high-performance semiconductor apparatus that requires sufficient electromagnetic wave shielding property.

### EXAMPLES

In the following, the present invention will be described more specifically by referring to Examples and Comparative Examples, but the present invention is not limited to Examples mentioned below.

### Production Example 1

A coating solution in which 50 g of partial hydrolysis condensate of methyltrimethoxysilane (Product name: KBM-13 available from Shin-Etsu Chemical Co., Ltd.) as an organosilicon compound had been added to 100 g of toluene was impregnated into a glass cloth (Used yarn: E250, density: 59 warp yarns/25 mm, 57 weft yarns/25 mm, thickness: 87 μm, mass: 95 g/m²), and the impregnated material was dried under heating at 100° C. for 10 minutes. Thereafter, the resultant was subjected to heat treatment at 100° C. for 1 hour and at 200° C. for 1 hour to prepare a surface-treated fibrous film (A1). The obtained surface-treated fibrous film was subjected to the following measurements.

### 1. Appearance

Surface uniformity of the obtained surface-treated fibrous film, i.e., whether the surface is smooth and whether a crack is present or not on the surface were visually confirmed.

### 2. Conventional Bending Rigidity

The conventional bending rigidity of the obtained surface-treated fibrous film was measured by the method described in JIS R 3420, and the ratio of conventional bending rigidity was calculated from the equation shown below.

Ratio of conventional bending rigidity=conventional bending rigidity of surface-treated fibrous film/conventional bending rigidity of untreated fibrous film

Also, from the obtained surface-treated fibrous film, a rectangular test piece having a width of 25 mm and a length of 250 mm was cut out from the fiber to be tested with each 6 pieces in the warp direction, and the following measurements were carried out.

### 3. Linear Expansion Coefficient

A sample having a width of 3 mm, a length of 25 mm and a thickness of 50 to 300 mm was cut from the obtained surface-treated fibrous film, and the sample was subjected to a tensile test using a thermomechanical analysis (TMA) apparatus (Name of apparatus: TMA/SS6000, manufactured by Seiko Instruments Inc.) in the temperature ranging from −60° C. to 200° C. with a temperature raising rate of 5° C./min while applying a load of 100 mN. The thermal expansion coefficient was calculated from an elongation amount of the surface-treated fibrous film relative to the temperature.

### 4. Flexibility Test of Film

The obtained surface-treated fibrous film was fitted into a peripheral part of a semi-cylindrical shaped housing 4 having a width of 100 mm and a radius of 75 mm as shown in FIG. 6, and crack and collapse of the surface-treated fibrous film 2 were observed.

The respective measurement results are shown in Table 1.

### Production Example 2

To 100 parts by mass of water were added 10 parts by mass of 3-glycidoxypropyltrimethoxysilane (Product name: KBM-403 available from Shin-Etsu Chemical Co., Ltd.) as an organosilicon compound, 0.02 part by mass of a surfactant, and 0.05 part by mass of acetic acid to prepare a coating solution. By using the coating solution, a surface-treated fibrous film (A2) was obtained in the same manner as in Production Example 1. By using the obtained surface-treated fibrous film, appearance, mechanical characteristics, and linear expansion coefficient were evaluated in the same manner as in Production Example 1.

### Production Example 3

To 100 g of an addition curing type resin in which an unsaturated group-containing organopolysiloxane having R¹SiO_{3/2} units and a hydrosilyl group-containing organopolysiloxane had been blended so that H/Vi is 1.1 was added octyl alcohol solution of 1% by mass of chloroplatinic acid so that the platinum is 10 ppm, and 100 g of toluene was added to the mixture to prepare a coating solution. By using the coating solution, a surface-treated fibrous film (A3) was obtained in the same manner as in Production Example 1. By using the obtained surface-treated fibrous film, appearance, mechanical characteristics, and linear expansion coefficient were evaluated in the same manner as in Production Example 1. It is to be noted that R¹ represents a phenyl group and Vi denotes a vinyl group represented by (—C═C).

### Production Example 4

To 100 g of an addition curing type resin in which an unsaturated group-containing organopolysiloxane having R¹SiO_{3/2} units and a hydrosilyl group-containing organopolysiloxane had been blended so that H/Vi is 1.1 was added octyl alcohol solution of 1% by mass of chloroplatinic acid so that the platinum is 10 ppm in the same manner as in Production Example 3, and 130 g of toluene was added to the mixture, and then, 185 g of alumina (Product name: Admafine AO-502, average particle diameter: about 0.7 μm, available from Admatechs Co., Ltd.) was further added to prepare a coating solution. By using the coating solution, a surface-treated fibrous film (A4) was obtained in the same manner as in Production Example 1. By using the obtained surface-treated fibrous film, appearance, mechanical characteristics, and linear expansion coefficient were evaluated in the same manner as in Production Example 1. It is to be noted that R¹ represents a phenyl group and Vi denotes a vinyl group represented by (—C═C).

### Comparative Production Example 1

5 g of 3-glycidoxypropyltrimethoxysilane (Product name: KBM-403, available from Shin-Etsu Chemical Co., Ltd.) was added to 95 g of toluene to prepare a coating solution. By using the coating solution, a surface-treated fibrous film (B1) was obtained in the same manner as in Production Example 1. By using the obtained surface-treated fibrous film, appearance, mechanical characteristics, and linear expansion coefficient were evaluated in the same manner as in Production Example 1.

### Comparative Production Example 2

3-glycidoxypropyltrimethoxysilane (Product name: KBM-403 available from Shin-Etsu Chemical Co., Ltd.) was charged into a mold having a size of 200 mm×240 mm×3 mm and treated with Teflon (Registered Trademark), a glass cloth (Used yarn: E250, density: 59 warp yarns/25 mm, 57 weft yarns/25 mm, thickness: 87 μm, mass: 95 g/m²) was immersed therein, and then, the material was dried under heating at 100° C. for 10 minutes to obtain a surface-treated fibrous film (B2). The adhesion amount of the organosilicon compound was 92% by mass, but large cracks were generated at the surface-treated fibrous film and the subsequent measurement could not be done.

### Comparative Production Example 3

By using a glass cloth (Used yarn: D450, density: 53 warp yarns/25 mm, 53 weft yarns/25 mm, thickness: 42 μm, mass: 47 g/m²) (B3) that had not been subjected to surface treatment, appearance, mechanical characteristics, and linear expansion coefficient were evaluated in the same manner as in Production Example 1.

TABLE 1

| | | | | | Comparative | Comparative | Comparative |
|---|---|---|---|---|---|---|---|
| | Production | Production | Production | Production | Production | Production | Production |
| | Example 1 | Example 2 | Example 3 | Example 4 | Example 1 | Example 2 | Example 3 |
| Fibrous film | A1 | A2 | A3 | A4 | B1 | B2 | B3 |
| Adhesion amount | 36.5 | 4.5 | 40.2 | 58.2 | 0.2 | 92.0 | 0 |
| (wt %) | | | | | | | |
| Appearance | good | good | good | good | good | crack | good |
| Ratio of | 18.7 | 6.3 | 20.4 | 53.2 | 1.3 | not | 1 |
| conventional | | | | | | measurable | |
| bending rigidity | | | | | | (>100) | |
| Linear expansion | 5 | 8 | 17 | 14 | 6 | not | not |
| coefficient | | | | | | measurable | measurable |
| (ppm/° C.) | | | | | | | |
| Flexibility | good | good | good | good | good | poor | good |
| of film*1 | | | | | | | |

*1Flexibility of film
good: Neither crack nor peeling
Poor: Crack or peeling present

As shown in Table 1, it could be understood that, when the glass fiber had not been subjected to surface treatment as demonstrated in Comparative Production Example 3, or when the adhesion amount of the organosilicon compound is too little as demonstrated in Comparative Production Example 1, the ratio of the conventional bending rigidity was low, the fibrous film did not have self-standing property, and the fiber was not fixed. On the other hand, when the adhesion amount of the organosilicon compound was too much as demonstrated in Comparative Production Example 2, cracks were generated at the surface. In the present invention, as demonstrated in Production Examples 1 to 4, the ratio of the conventional bending rigidity was made 3 to 100 times by adjusting the adhesion amount, whereby the surface-treated fibrous films A1 to A4 having high strength and good flexibility were obtained. By using the surface-treated fibrous films A1 to A4, electromagnetic wave shielding sheets were prepared by the method described below, and then evaluated.

### Example 1

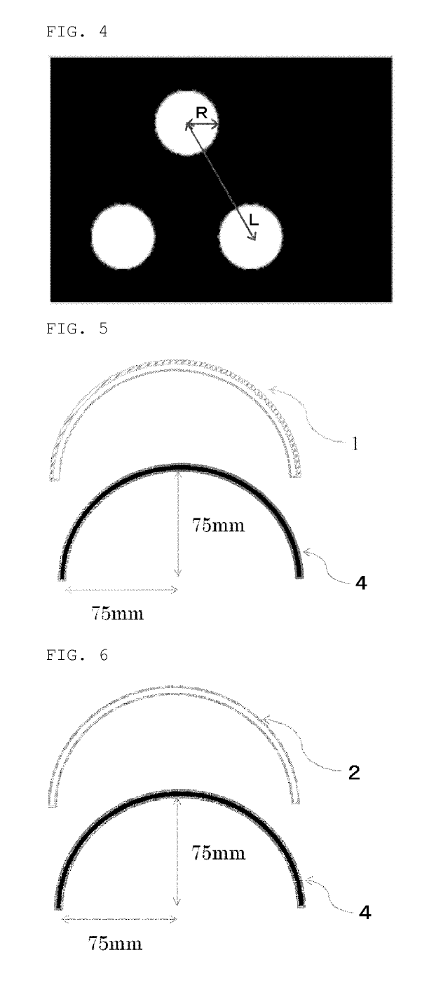

A sheet of the surface-treated fibrous film (A1) obtained in Production Example 1 and a copper foil (available from Fukuda Metal Foil & Powder Co., Ltd., thickness: 18 μm) as a conductive layer were provided, an adhesive layer made of a silicone resin (Product name: KE-109, available from Shin-Etsu Chemical Co., Ltd.) was applied between the surface-treated fibrous film and the copper foil, the material was then molded under pressure by a hot pressing apparatus at 150° C. for 30 minutes, and the resulting material was further secondary cured at 150° C. for one hour. Then, a mesh pattern having a radius R of the opening of 0.5 mm and a distance L between centers of 1.8 mm as shown in FIGS. 2 and 4 was formed on the copper foil constituting the conductive layer to obtain an electromagnetic wave shielding sheet (C1) (length: 50 mm, width: 200 mm). The open area ratio of the conductive layer of the obtained electromagnetic wave shielding sheet was 28%. When the obtained electromagnetic wave shielding sheet was fitted into a peripheral part of a semi-cylindrical shaped housing 4 having a width of 100 mm and a radius of 75 mm as shown in FIG. 5, crack and collapse of the surface-treated fibrous film were not observed.

### 5. Electromagnetic Wave Shielding Property

With respect to the obtained electromagnetic wave shielding sheets, shielding effect (decibel, unit: dB) was measured by using a KEC method (KEC: Kansai Electronic Industry Development Center) under conditions that frequency was 100 MHz to 1000 MHz, distance between transmitting part and receiving part was 10 mm, and temperature and humidity in test room was 20° C./65% RH. When the shielding effect is 30 dB or more in measuring frequency, electromagnetic wave shielding property is found.

### 6. Heat Resistance

The obtained electromagnetic wave shielding sheet was subjected to IR reflow treatment at 260° C. for 60 seconds by an IR reflow apparatus, and then, swelling of the surface was visually observed.

7. Warpage Before and after IR Reflow Test

Warpage (unit: mm) of the obtained electromagnetic wave shielding sheets in the longitudinal direction was measured before and after subjecting to an IR reflow treatment at 260° C. for 60 seconds by using an IR reflow apparatus (Name of apparatus: TNR15-225LH, manufactured by TAMURA Corporation).

The respective measurement results are shown in Table 2.

### Example 2

A sheet of the surface-treated fibrous film (A1) obtained in Production Example 1 was molded under pressure by a hot pressing apparatus at 150° C. for 30 minutes, and the resulting material was further secondary cured at 150° C. for one hour. Then, a mesh pattern having a radius R of the opening of 0.8 mm and a distance L between centers of 1.8 mm as shown in FIGS. 2 and 4 was formed by electroless plating with copper and electroplating with copper to obtain an electromagnetic wave shielding sheet (C2) (length: 50 mm, width: 200 mm). The open area ratio of, the conductive layer of the obtained electromagnetic wave shielding sheet was 72%. When the obtained electromagnetic wave shielding sheet was fitted into a peripheral part of a semi-cylindrical shaped housing 4 having a width of 100 mm and a radius of 75 mm as shown in FIG. 5, crack and collapse of the surface-treated fibrous film were not observed. By using the obtained electromagnetic wave shielding sheet, electromagnetic wave shielding property, heat resistance, and IR reflow test were evaluated in the same manner as in Example 1.

### Example 3

A sheet of the surface-treated fibrous film (A1) obtained in Production Example 1 and a copper foil (available from Fukuda Metal Foil & Powder Co., Ltd., thickness: 18 μm) as a conductive layer were provided, an adhesive layer made of a silicone resin (Product name: KE-109, available from Shin-Etsu Chemical Co., Ltd.) was applied between the surface-treated fibrous film and the copper foil, then the material was molded under heating in the same manner as in Example 1. Then, a mesh pattern having a radius R of the opening of 0.5 mm and a distance L between centers of 1.8 mm and divided into 4 regions (length: 50 mm, width: 49.9 mm) with an interval of 0.1 mm as shown in FIGS. 3 and 4 was formed on the copper foil constituting the conductive layer to obtain an electromagnetic wave shielding sheet (C3) (length: 50 mm, width: 200 mm). The open area ratio of the conductive layer of the obtained electromagnetic wave shielding sheet was 28%. When the obtained electromagnetic wave shielding sheet was fitted into a peripheral part of a semi-cylindrical shaped housing 4 having a width of 100 mm and a radius of 75 mm as shown in FIG. 5, crack and collapse of the surface-treated fibrous film were not observed. By using the obtained electromagnetic wave shielding sheet, electromagnetic wave shielding property, heat resistance, and IR reflow test were evaluated in the same manner as in Example 1.

### Example 4

By using a sheet of the surface-treated fibrous film (A2) obtained in Production Example 2 and a sheet of 300-mesh stainless steel wire net (mesh: 300 mesh/2.54 cm, opening size: 55 μm, open area ratio: 42%, wire diameter: 30 μm, thickness: 70 μm), molding was performed under pressure by a hot pressing apparatus at 150° C. for 30 minutes, and the resulting material was further secondary cured at 150° C. for one hour to obtain an electromagnetic wave shielding sheet (C4). By using the obtained electromagnetic wave shielding sheet, electromagnetic wave shielding property, heat resistance, and IR reflow test were evaluated in the same manner as in Example 1.

### Example 5

By using two sheets of the surface-treated fibrous film (A3) obtained in Production Example 3 and a sheet of 300-mesh stainless steel wire net (mesh: 300 mesh/2.54 cm, opening size: 55 μm, open area ratio: 42%, wire diameter: 30 μm, thickness: 70 μm), molding was performed under heating in the same manner as in Example 4. Further, on the steel wire net were placed two sheets of the surface-treated fibrous film (A3) similarly obtained in Production Example 3 and the same 300-mesh stainless steel wire net as mentioned above, and molding was performed under heating in the same manner to obtain a laminated electromagnetic wave shielding sheet (C5). The open area ratio of the conductive layer of the obtained electromagnetic wave shielding sheet was 30%. When the obtained electromagnetic wave shielding sheet was fitted into a peripheral part of a semi-cylindrical shaped housing 4 having a width of 100 mm and a radius of 75 mm as shown in FIG. 5, crack and collapse of the surface-treated fibrous film were not observed. By using the obtained electromagnetic wave shielding sheet, electromagnetic wave shielding property, heat resistance, and IR reflow test were evaluated in the same manner as in Example 1.

### Example 6

By using a sheet of the surface-treated fibrous film (A4) obtained in Production Example 4 and a sheet of 300-mesh stainless steel wire net (mesh: 300 mesh/2.54 cm, opening size: 55 μm, open area ratio: 42%, wire diameter: 30 μm, thickness: 70 μm), molding was performed under pressure by a hot pressing apparatus at 150° C. for 30 minutes, and the resulting material was further secondary cured at 150° C. for one hour to obtain an electromagnetic wave shielding sheet (C6). By using the obtained electromagnetic wave shielding sheet, electromagnetic wave shielding property, heat resistance, and IR reflow test were evaluated in the same manner as in Example 1.

### Comparative Example 1

As a conductive layer, a copper foil (available from Fukuda Metal Foil & Powder Co., Ltd., thickness: 18 μm) was placed on one side of a sheet of the surface-treated fibrous film (A1) obtained in Production Example 1, and an adhesive layer made of a silicone resin (Product name: KE-109, available from Shin-Etsu Chemical Co., Ltd.) was applied between the surface-treated fibrous film and the copper foil. Then, the material was molded under pressure by a hot pressing apparatus at 150° C. for 30 minutes, and further secondary cured at 150° C. for one hour to obtain an electromagnetic wave shielding sheet (D1) (length: 50 mm, width: 200 mm). The open area ratio of the conductive layer of the obtained electromagnetic wave shielding sheet was 0%. By using the obtained electromagnetic wave shielding sheet, electromagnetic wave shielding property, heat resistance, and IR reflow test were evaluated in the same manner as in Example 1.

### Comparative Example 2

Using 180 g of a commercially available addition reaction curing type silicone varnish (Product name: KJR-632 available from Shin-Etsu Chemical Co., Ltd.), 200 g of toluene was added thereto as a solvent, and further, 189 g of silica (Product name: Admafine E5/24C, average particle diameter: about 3 μm, available from Admatechs Co., Ltd.) was added to obtain a toluene dispersion. Into the toluene dispersion was immersed the surface-treated fibrous film (B1) obtained in Comparative Production Example 1, and the material was dried at 100° C. for 10 minutes to obtain a support in the uncured state. By using a sheet of the obtained support and a copper foil (available from Fukuda Metal Foil & Powder Co., Ltd., thickness: 18 μm) as a conductive layer, molding was performed under heating in the same manner as in Comparative Example 1 to obtain an electromagnetic wave shielding sheet (D2) (length: 50 mm, width: 200 mm). The open area ratio of the conductive layer of the obtained electromagnetic wave shielding sheet was 0%. By using the obtained electromagnetic wave shielding sheet, electromagnetic wave shielding property, heat resistance, and IR reflow test were evaluated in the same manner as in Example 1.

### Comparative Example 3

Two sheets of the surface-treated fibrous film (A3) obtained in Production Example 3 was molded under heating together with a conductive layer in the same manner as in Comparative Example 1. Further, on the conductive layer were placed two sheets of the surface-treated fibrous film (A3) similarly obtained in Production Example 3 and the same copper foil (available from Fukuda Metal Foil & Powder Co., Ltd., thickness: 18 μm) as mentioned above, and molding was performed under heating in the same manner to obtain a laminated electromagnetic wave shielding sheet (D3). The open area ratio of the conductive layer of the obtained electromagnetic wave shielding sheet was 0%. By using the obtained electromagnetic wave shielding sheet, electromagnetic wave shielding property, heat resistance, and IR reflow test were evaluated in the same manner as in Example 1.

### Comparative Example 4

A mesh pattern having a radius R of the opening of 0.8 mm and a distance L between centers of 1.8 mm as shown in FIGS. 2 and 4 was formed on a long-roll polyethylene terephthalate (PET) film having a thickness of 100 μm by electroless plating with copper and electroplating with copper to obtain an electromagnetic wave shielding sheet (D4) (length: 50 mm, width: 200 mm). The open area ratio of the conductive layer of the obtained electromagnetic wave shielding sheet was 72%. By using the obtained electromagnetic wave shielding sheet, electromagnetic wave shielding property, heat resistance, and IR reflow test were evaluated in the same manner as in Example 1.

TABLE 2

| | | | | | | | Comparative | Comparative | Comparative | Comparative |
|---|---|---|---|---|---|---|---|---|---|---|
| | Example 1 | Example 2 | Example 3 | Example 4 | Example 5 | Example 6 | Example 1 | Example 2 | Example 3 | Example 4 |
| Film | A1 | A1 | A1 | A2 | A3 | A4 | A1 | B1 | A3 | PET film |
| Open area ratio | 28 | 72 | 28 | 42 | 30 | 42 | 0 | 0 | 0 | 72 |
| (%) | | | | | | | | | | |
| Region | 1 | 1 | 4 | 1 | 1 | 1 | 1 | 1 | 1 | 1 |
| Number of | 1 | 1 | 1 | 1 | 2 | 1 | 1 | 1 | 2 | 1 |
| laminating | | | | | | | | | | |
| Electromagnetic | good | good | good | good | good | good | good | good | good | good |
| wave shielding | | | | | | | | | | |
| property *2 | | | | | | | | | | |
| Heat resistance | no | no | no | no | no | no | no | no | swell | no |
| | swell | swell | swell | swell | swell | swell | swell | swell | | swell |
| Warp before IR | 10 | 6 | 2 | 7 | 6 | 4 | crack | crack | 15 | crack |
| reflow test (mm) | | | | | | | | | | |
| Warp after IR | 11 | 6 | 4 | 9 | 8 | 5 | crack | crack | 19 | crack |
| reflow test (mm) | | | | | | | | | | |

*2 Electromagnetic wave shielding property
good: Electromagnetic wave shielding effect is 30 dB or more in measuring frequency
poor: Electromagnetic wave shielding effect is less than 30 dB in measuring frequency

As shown in Table 2, when a surface-treated fibrous film having high strength and good flexibility and a conductive layer composed of a metallic mesh are used as demonstrated in Examples 1 to 6, a high-reliability electromagnetic wave shielding sheet having high heat resistance and inhibited from warping and swelling can be obtained. Also, using the surface-treated fibrous film having high strength and flexibility enables an electromagnetic wave shielding sheet having the same characteristics to be obtained, so that it is applicable to a semiconductor apparatus that requires flexibility and high heat resistance or a high-performance semiconductor apparatus that requires sufficient electromagnetic wave shielding property.

On the other hand, when the metallic mesh is not used as the conductive layer as demonstrated in Comparative Examples 1 to 3, or when the surface-treated fibrous film is not used as demonstrated in Comparative Example 4, heat resistance is inferior.

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. An electromagnetic wave shielding sheet comprising a surface-treated fibrous film and a conductive layer,
the surface-treated fibrous film having a conventional bending rigidity 3 to 100 times larger than a conventional bending rigidity of a untreated fibrous film as measured according to a procedure described in Japanese Industrial Standards R 3420, the conductive layer being composed of a metallic mesh.

2. The electromagnetic wave shielding sheet according to claim 1, wherein an open area ratio of the metallic mesh is 10% or more and 90% or less.

3. The electromagnetic wave shielding sheet according to claim 1, wherein a thickness of the metallic mesh is 0.05 μm or more and 200 μm or less.

4. The electromagnetic wave shielding sheet according to claim 2, wherein a thickness of the metallic mesh is 0.05 μm or more and 200 μm or less.

5. The electromagnetic wave shielding sheet according to claim 1, wherein the electromagnetic wave shielding sheet is bendable at 90° or more.

6. The electromagnetic wave shielding sheet according to claim 2, wherein the electromagnetic wave shielding sheet is bendable at 90° or more.

7. The electromagnetic wave shielding sheet according to claim 3, wherein the electromagnetic wave shielding sheet is bendable at 90° or more.

8. The electromagnetic wave shielding sheet according to claim 4, wherein the electromagnetic wave shielding sheet is bendable at 90° or more.

9. The electromagnetic wave shielding sheet according to claim 1, wherein the surface-treated fibrous film includes glass fibers, and a part or all of the glass fibers are surface-treated and bundled by a cured product of an organosilicon compound.

10. The electromagnetic wave shielding sheet according to claim 2, wherein the surface-treated fibrous film includes glass fibers, and a part or all of the glass fibers are surface-treated and bundled by a cured product of an organosilicon compound.

11. The electromagnetic wave shielding sheet according to claim 3, wherein the surface-treated fibrous film includes glass fibers, and a part or all of the glass fibers are surface-treated and bundled by a cured product of an organosilicon compound.

12. The electromagnetic wave shielding sheet according to claim 4, wherein the surface-treated fibrous film includes glass fibers, and a part or all of the glass fibers are surface-treated and bundled by a cured product of an organosilicon compound.

13. The electromagnetic wave shielding sheet according to claim 9, wherein the organosilicon compound is one or more compounds selected from the group consisting of alkoxysilane, polysilazane, partial hydrolysis condensates thereof, a silicone-modified varnish, and an addition curing type silicone resin.

14. The electromagnetic wave shielding sheet according to claim 10, wherein the organosilicon compound is one or more compounds selected from the group consisting of alkoxysilane, polysilazane, partial hydrolysis condensates thereof, a silicone-modified varnish, and an addition curing type silicone resin.

15. The electromagnetic wave shielding sheet according to claim 11, wherein the organosilicon compound is one or more compounds selected from the group consisting of alkoxysilane, polysilazane, partial hydrolysis condensates thereof, a silicone-modified varnish, and an addition curing type silicone resin.

16. The electromagnetic wave shielding sheet according to claim 12, wherein the organosilicon compound is one or more compounds selected from the group consisting of alkoxysilane, polysilazane, partial hydrolysis condensates thereof, a silicone-modified varnish, and an addition curing type silicone resin.

17. The electromagnetic wave shielding sheet according to claim 1, wherein the surface-treated fibrous film contains a filler.

18. The electromagnetic wave shielding sheet according to claim 1, wherein the conductive layer and a layer having a sheet of the surface-treated fibrous film or two or more sheets of the surface-treated fibrous film being laminated are laminated alternately and repeatedly one or more times.

19. The electromagnetic wave shielding sheet according to claim 1, wherein the metallic mesh is divided into two or more regions.

20. A semiconductor apparatus that is prepared by using the electromagnetic wave shielding sheet according to claim 1.
